(19) United States
(12) Patent Application Publication
(10) Pub. No.: US 2015/0349924 A1
(43) Pub. Date: Dec. 3, 2015

(54) LINK BUDGET IMPROVEMENT IN PEER DISCOVERY

(71) Applicant: QUALCOMM Incorporated, San Diego, CA (US)

(72) Inventors: Hua WANG, Basking Ridge, NJ (US); Avhishek CHATTERJEE, Austin, TX (US); Shailesh PATIL, Bridgewater, NJ (US); Junyi LI, Chester, NJ (US)

(73) Assignee: QUALCOMM Incorporated, San Diego, CA (US)

(21) Appl. No.: 14/289,631

(22) Filed: May 28, 2014

(51) Int. Cl. H04L 1/00; H04W 40/24; H03M 13/00; G06F 11/10

(52) U.S. Cl. CPC H04L 1/0061; G06F 11/1004; H04W 40/246; H04L 1/0041; H03M 13/005

(57) ABSTRACT

In an aspect, a method, an apparatus, and a computer program product for wireless communication are provided. The apparatus codes a peer discovery message for peer discovery. The apparatus generates a plurality of different redundancy versions of the coded peer discovery message. The apparatus transmits each of the different redundancy versions of the coded peer discovery message in a different allocated time period. In another aspect, a method, an apparatus, and a computer program product for wireless communication are provided. The apparatus receives at least one redundancy version of a coded peer discovery message. The apparatus attempts to decode the received at least one redundancy version of the coded peer discovery message.

### BACKGROUND

1. Field

The present disclosure relates generally to communication systems, and more particularly, to link budget improvement in peer discovery.

2. Background

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example of an emerging telecommunication standard is Long Term Evolution (LTE). LTE is a set of enhancements to the Universal Mobile Telecommunications System (UMTS) mobile standard promulgated by Third Generation Partnership Project (3GPP). LTE is designed to better support mobile broadband Internet access by improving spectral efficiency, lowering costs, improving services, making use of new spectrum, and better integrating with other open standards using OFDMA on the downlink (DL), SC-FDMA on the uplink (UL), and multiple-input multiple-output (MIMO) antenna technology. However, as the demand for mobile broadband access continues to increase, there exists a need for further improvements in LTE technology. Preferably, these improvements should be applicable to other multi-access technologies and the telecommunication standards that employ these technologies.

### SUMMARY

In an aspect of the disclosure, a method, a computer program product, and an apparatus are provided. The apparatus may be a user equipment (UE). The apparatus codes a peer discovery message for peer discovery. The apparatus generates a plurality of different redundancy versions of the coded peer discovery message. The apparatus transmits each of the different redundancy versions of the coded peer discovery message in a different allocated time period.

The apparatus may include a memory and at least one processor coupled to the memory and configured to code a peer discovery message for peer discovery. The at least one processor may be configured to generate a plurality of different redundancy versions of the coded peer discovery message transmit each of the different redundancy versions of the coded peer discovery message in a different allocated time period.

The computer program product stored on a computer-readable medium and comprising code that when executed on at least one processor performs the steps of coding a peer discovery message for peer discovery, generating a plurality of different redundancy versions of the coded peer discovery message, and transmitting each of the different redundancy versions of the coded peer discovery message in a different allocated time period.

In another aspect of the disclosure, a method, a computer program product, and an apparatus are provided. The apparatus may be a UE. The apparatus receives at least one redundancy version of a coded peer discovery message. The apparatus attempts to decode the received at least one redundancy version of the coded peer discovery message.

The apparatus may include means for receiving at least one redundancy version of a coded peer discovery message and means for attempting to decode the received at least one redundancy version of the coded peer discovery message.

The apparatus may include a memory and at least one processor coupled to the memory and configured to receive at least one redundancy version of a coded peer discovery message and to attempt to decode the received at least one redundancy version of the coded peer discovery message.

The computer program product stored on a computer-readable medium and comprising code that when executed on at least one processor performs the steps of receiving at least one redundancy version of a coded peer discovery message and attempting to decode the received at least one redundancy version of the coded peer discovery message.

### BRIEF DESCRIPTION OF THE DRAWINGS

FIG. 1 is a diagram illustrating an example of a network architecture.

FIG. 2 is a diagram illustrating an example of an access network.

FIG. 3 is a diagram illustrating an example of a DL frame structure in LTE.

FIG. 4 is a diagram illustrating an example of an UL frame structure in LTE.

FIG. 5 is a diagram illustrating an example of a radio protocol architecture for the user and control planes.

FIG. 6 is a diagram illustrating an example of an evolved Node B and user equipment in an access network.

FIG. 7 is a diagram of a device-to-device communications system.

FIG. 8 is a diagram for illustrating an exemplary method for improving link budget in peer discovery using multiple redundant versions.

FIG. 9 is a diagram for illustrating an exemplary method for improving link budget in peer discovery.

FIG. 10 is a flow chart of a method for improving link budget in peer discovery.

FIG. 11 is a flow chart of a method for improving link budget in peer discovery.

FIG. 12 is a conceptual data flow diagram illustrating the data flow between different modules/means/components in an exemplary apparatus.

FIG. 13 is a diagram illustrating an example of a hardware implementation for an apparatus employing a processing system.

FIG. 14 is a conceptual data flow diagram illustrating the data flow between different modules/means/components in an exemplary apparatus.

FIG. 15 is a diagram illustrating an example of a hardware implementation for an apparatus employing a processing system.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), compact disk ROM (CD-ROM) or other optical disk storage, magnetic disk storage or other magnetic storage devices, or any other medium that can be used to carry or store desired program code in the form of instructions or data structures and that can be accessed by a computer. Combinations of the above should also be included within the scope of computer-readable media.

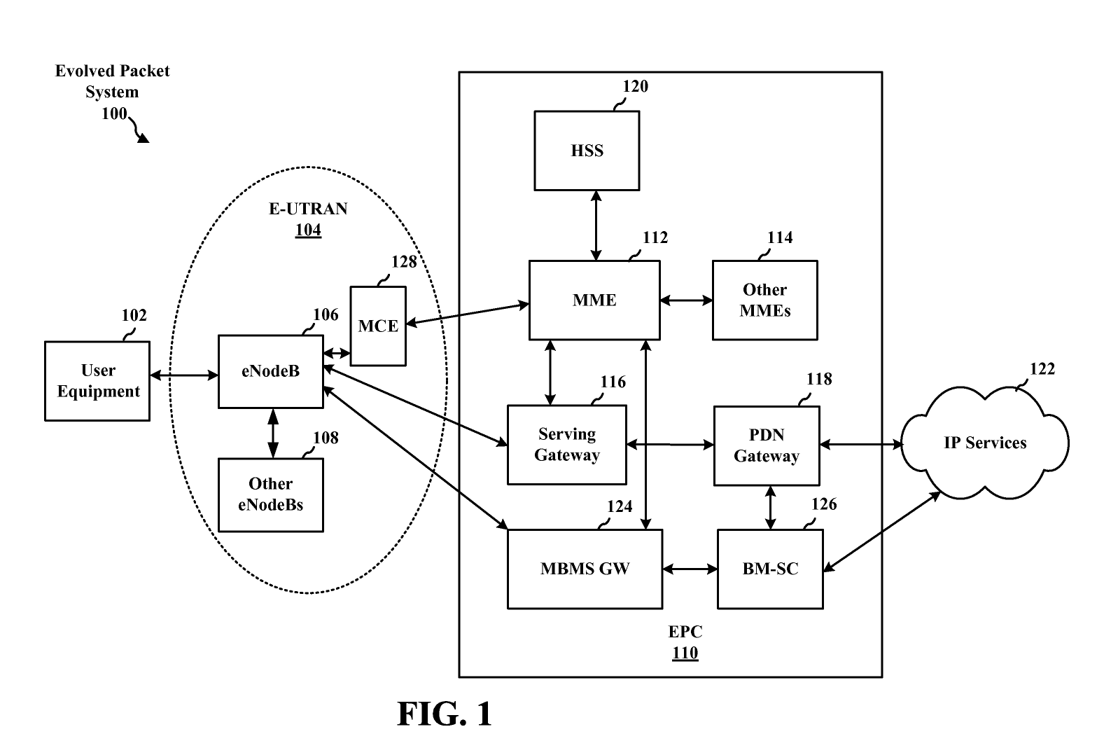

FIG. 1 is a diagram illustrating an LTE network architecture 100. The LTE network architecture 100 may be referred to as an Evolved Packet System (EPS) 100. The EPS 100 may include one or more user equipment (UE) 102, an Evolved UMTS Terrestrial Radio Access Network (E-UTRAN) 104, an Evolved Packet Core (EPC) 110, and an Operator's Internet Protocol (IP) Services 122. The EPS can interconnect with other access networks, but for simplicity those entities/interfaces are not shown. As shown, the EPS provides packet-switched services, however, as those skilled in the art will readily appreciate, the various concepts presented throughout this disclosure may be extended to networks providing circuit-switched services.

The E-UTRAN includes the evolved Node B (eNB) 106 and other eNBs 108, and may include a Multicast Coordination Entity (MCE) 128. The eNB 106 provides user and control planes protocol terminations toward the UE 102. The eNB 106 may be connected to the other eNBs 108 via a backhaul (e.g., an X2 interface). The MCE 128 allocates time/frequency radio resources for evolved Multimedia Broadcast Multicast Service (MBMS) (eMBMS), and determines the radio configuration (e.g., a modulation and coding scheme (MCS)) for the eMBMS. The MCE 128 may be a separate entity or part of the eNB 106. The eNB 106 may also be referred to as a base station, a Node B, an access point, a base transceiver station, a radio base station, a radio transceiver, a transceiver function, a basic service set (BSS), an extended service set (ESS), or some other suitable terminology. The eNB 106 provides an access point to the EPC 110 for a UE 102. Examples of UEs 102 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, or any other similar functioning device. The UE 102 may also be referred to by those skilled in the art as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology.

The eNB 106 is connected to the EPC 110. The EPC 110 may include a Mobility Management Entity (MME) 112, a Home Subscriber Server (HSS) 120, other MMEs 114, a Serving Gateway 116, a Multimedia Broadcast Multicast Service (MBMS) Gateway 124, a Broadcast Multicast Service Center (BM-SC) 126, and a Packet Data Network (PDN) Gateway 118. The MME 112 is the control node that processes the signaling between the UE 102 and the EPC 110. Generally, the MME 112 provides bearer and connection management. All user IP packets are transferred through the Serving Gateway 116, which itself is connected to the PDN Gateway 118. The PDN Gateway 118 provides UE IP address allocation as well as other functions. The PDN Gateway 118 and the BM-SC 126 are connected to the IP Services 122. The IP Services 122 may include the Internet, an intranet, an IP Multimedia Subsystem (IMS), a PS Streaming Service (PSS), and/or other IP services. The BM-SC 126 may provide functions for MBMS user service provisioning and delivery. The BM-SC 126 may serve as an entry point for content provider MBMS transmission, may be used to authorize and initiate MBMS Bearer Services within a PLMN, and may be used to schedule and deliver MBMS transmissions. The MBMS Gateway 124 may be used to distribute MBMS traffic to the eNBs (e.g., 106, 108) belonging to a Multicast Broadcast Single Frequency Network (MBSFN) area broadcasting a particular service, and may be responsible for session management (start/stop) and for collecting eMBMS related charging information.

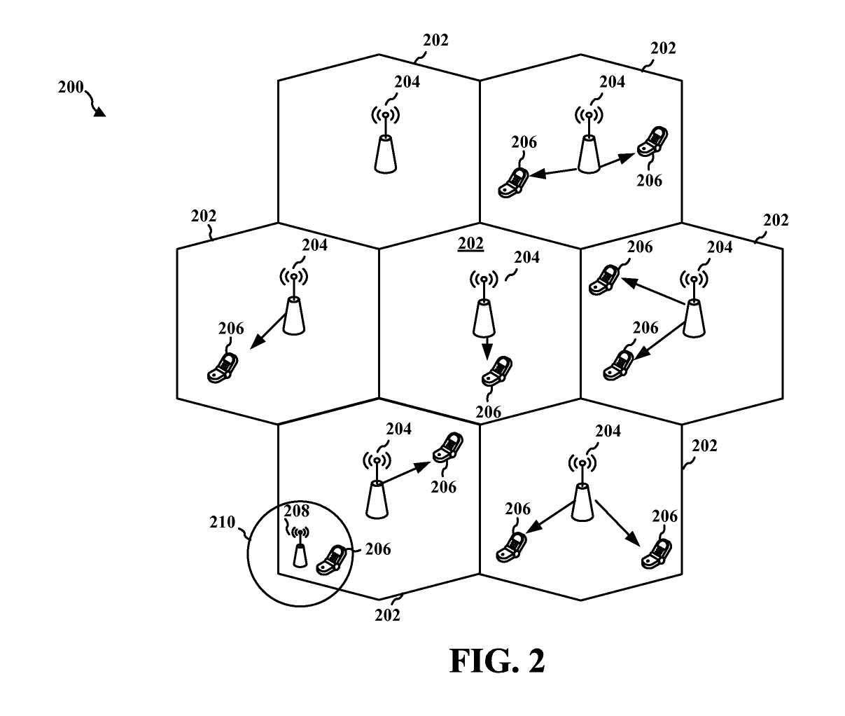

FIG. 2 is a diagram illustrating an example of an access network 200 in an LTE network architecture. In this example, the access network 200 is divided into a number of cellular regions (cells) 202. One or more lower power class eNBs 208 may have cellular regions 210 that overlap with one or more of the cells 202. The lower power class eNB 208 may be a femto cell (e.g., home eNB (HeNB)), pico cell, micro cell, or remote radio head (RRH). The macro eNBs 204 are each assigned to a respective cell 202 and are configured to provide an access point to the EPC 110 for all the UEs 206 in the cells 202. There is no centralized controller in this example of an access network 200, but a centralized controller may be used in alternative configurations. The eNBs 204 are responsible for all radio related functions including radio bearer control, admission control, mobility control, scheduling, security, and connectivity to the serving gateway 116. An eNB may support one or multiple (e.g., three) cells (also referred to as a sectors). The term “cell” can refer to the smallest coverage area of an eNB and/or an eNB subsystem serving are particular coverage area. Further, the terms “eNB,” “base station,” and “cell” may be used interchangeably herein.

The modulation and multiple access scheme employed by the access network 200 may vary depending on the particular telecommunications standard being deployed. In LTE applications, OFDM is used on the DL and SC-FDMA is used on the UL to support both frequency division duplex (FDD) and time division duplex (TDD). As those skilled in the art will readily appreciate from the detailed description to follow, the various concepts presented herein are well suited for LTE applications. However, these concepts may be readily extended to other telecommunication standards employing other modulation and multiple access techniques. By way of example, these concepts may be extended to Evolution-Data Optimized (EV-DO) or Ultra Mobile Broadband (UMB). EV-DO and UMB are air interface standards promulgated by the 3rd Generation Partnership Project 2 (3GPP2) as part of the CDMA2000 family of standards and employs CDMA to provide broadband Internet access to mobile stations. These concepts may also be extended to Universal Terrestrial Radio Access (UTRA) employing Wideband-CDMA (W-CDMA) and other variants of CDMA, such as TD-SCDMA; Global System for Mobile Communications (GSM) employing TDMA; and Evolved UTRA (E-UTRA), IEEE 802.11 (Wi-Fi), IEEE 802.16 (WiMAX), IEEE 802.20, and Flash-OFDM employing OFDMA. UTRA, E-UTRA, UMTS, LTE and GSM are described in documents from the 3GPP organization. CDMA2000 and UMB are described in documents from the 3GPP2 organization. The actual wireless communication standard and the multiple access technology employed will depend on the specific application and the overall design constraints imposed on the system.

The eNBs 204 may have multiple antennas supporting MIMO technology. The use of MIMO technology enables the eNBs 204 to exploit the spatial domain to support spatial multiplexing, beamforming, and transmit diversity. Spatial multiplexing may be used to transmit different streams of data simultaneously on the same frequency. The data streams may be transmitted to a single UE 206 to increase the data rate or to multiple UEs 206 to increase the overall system capacity. This is achieved by spatially precoding each data stream (i.e., applying a scaling of an amplitude and a phase) and then transmitting each spatially precoded stream through multiple transmit antennas on the DL. The spatially precoded data streams arrive at the UE(s) 206 with different spatial signatures, which enables each of the UE(s) 206 to recover the one or more data streams destined for that UE 206. On the UL, each UE 206 transmits a spatially precoded data stream, which enables the eNB 204 to identify the source of each spatially precoded data stream.

Spatial multiplexing is generally used when channel conditions are good. When channel conditions are less favorable, beamforming may be used to focus the transmission energy in one or more directions. This may be achieved by spatially precoding the data for transmission through multiple antennas. To achieve good coverage at the edges of the cell, a single stream beamforming transmission may be used in combination with transmit diversity.

In the detailed description that follows, various aspects of an access network will be described with reference to a MIMO system supporting OFDM on the DL. OFDM is a spread-spectrum technique that modulates data over a number of subcarriers within an OFDM symbol. The subcarriers are spaced apart at precise frequencies. The spacing provides “orthogonality” that enables a receiver to recover the data from the subcarriers. In the time domain, a guard interval (e.g., cyclic prefix) may be added to each OFDM symbol to combat inter-OFDM-symbol interference. The UL may use SC-FDMA in the form of a DFT-spread OFDM signal to compensate for high peak-to-average power ratio (PAPR).

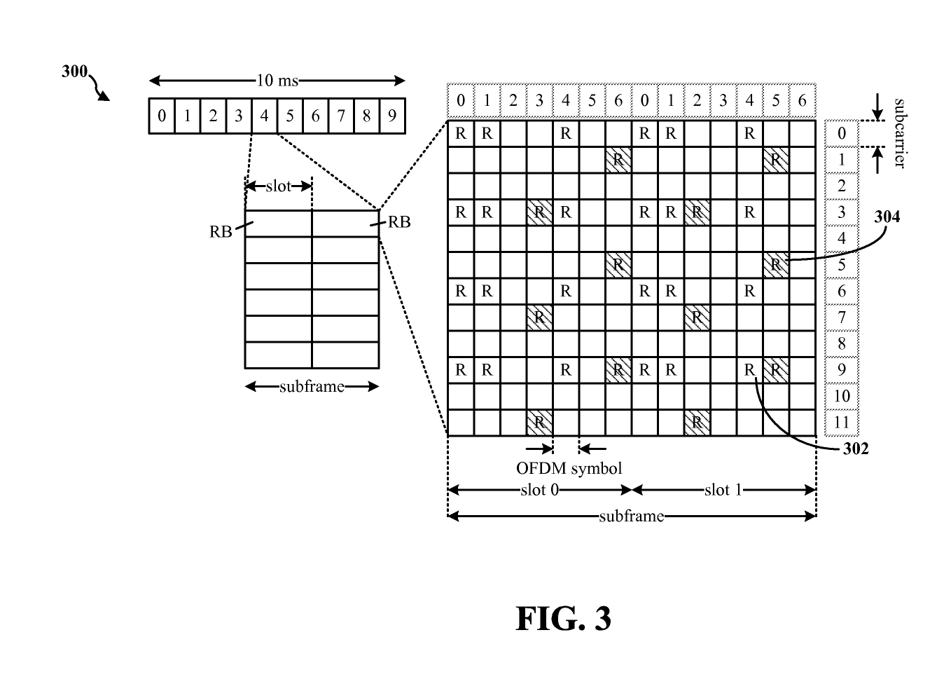

FIG. 3 is a diagram 300 illustrating an example of a DL frame structure in LTE. A frame (10 ms) may be divided into 10 equally sized subframes. Each subframe may include two consecutive time slots. A resource grid may be used to represent two time slots, each time slot including a resource block. The resource grid is divided into multiple resource elements. In LTE, for a normal cyclic prefix, a resource block contains 12 consecutive subcarriers in the frequency domain and 7 consecutive OFDM symbols in the time domain, for a total of 84 resource elements. For an extended cyclic prefix, a resource block contains 12 consecutive subcarriers in the frequency domain and 6 consecutive OFDM symbols in the time domain, for a total of 72 resource elements. Some of the resource elements, indicated as R 302, 304, include DL reference signals (DL-RS). The DL-RS include Cell-specific RS (CRS) (also sometimes called common RS) 302 and UE-specific RS (UE-RS) 304. UE-RS 304 are transmitted only on the resource blocks upon which the corresponding physical DL shared channel (PDSCH) is mapped. The number of bits carried by each resource element depends on the modulation scheme. Thus, the more resource blocks that a UE receives and the higher the modulation scheme, the higher the data rate for the UE.

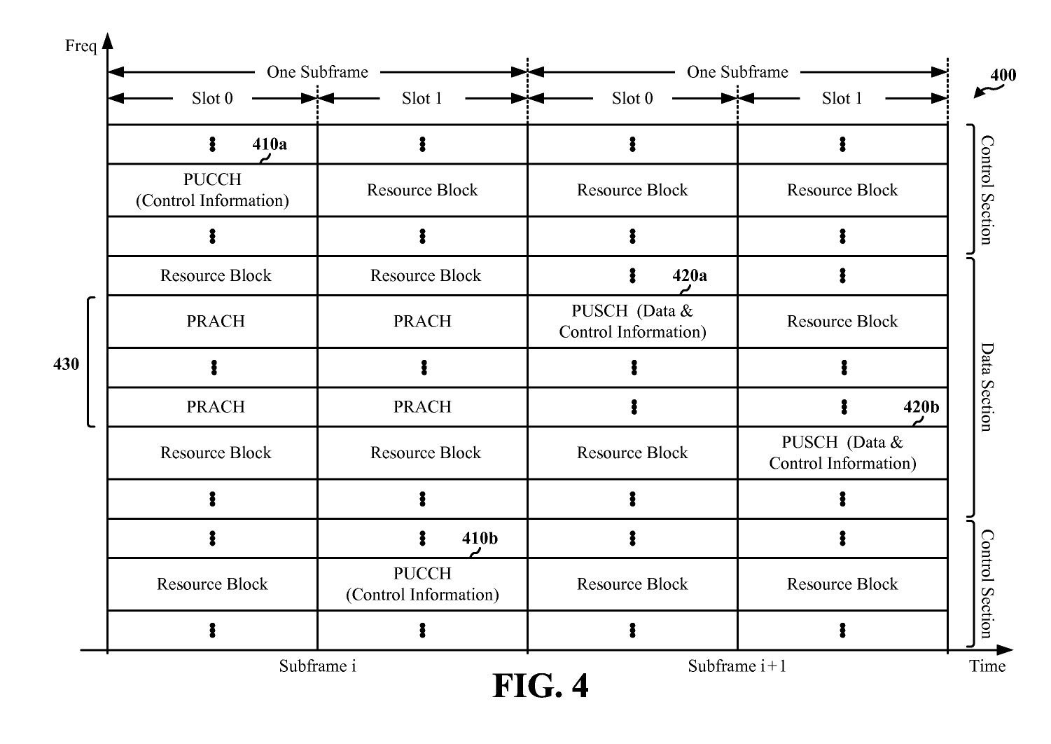

FIG. 4 is a diagram 400 illustrating an example of an UL frame structure in LTE. The available resource blocks for the UL may be partitioned into a data section and a control section. The control section may be formed at the two edges of the system bandwidth and may have a configurable size. The resource blocks in the control section may be assigned to UEs for transmission of control information. The data section may include all resource blocks not included in the control section. The UL frame structure results in the data section including contiguous subcarriers, which may allow a single UE to be assigned all of the contiguous subcarriers in the data section.

A UE may be assigned resource blocks 410a, 410b in the control section to transmit control information to an eNB. The UE may also be assigned resource blocks 420a, 420b in the data section to transmit data to the eNB. The UE may transmit control information in a physical UL control channel (PUCCH) on the assigned resource blocks in the control section. The UE may transmit only data or both data and control information in a physical UL shared channel (PUSCH) on the assigned resource blocks in the data section. A UL transmission may span both slots of a subframe and may hop across frequency.

A set of resource blocks may be used to perform initial system access and achieve UL synchronization in a physical random access channel (PRACH) 430. The PRACH 430 carries a random sequence and cannot carry any UL data/signaling. Each random access preamble occupies a bandwidth corresponding to six consecutive resource blocks. The starting frequency is specified by the network. That is, the transmission of the random access preamble is restricted to certain time and frequency resources. There is no frequency hopping for the PRACH. The PRACH attempt is carried in a single subframe (1 ms) or in a sequence of few contiguous subframes and a UE can make only a single PRACH attempt per frame (10 ms).

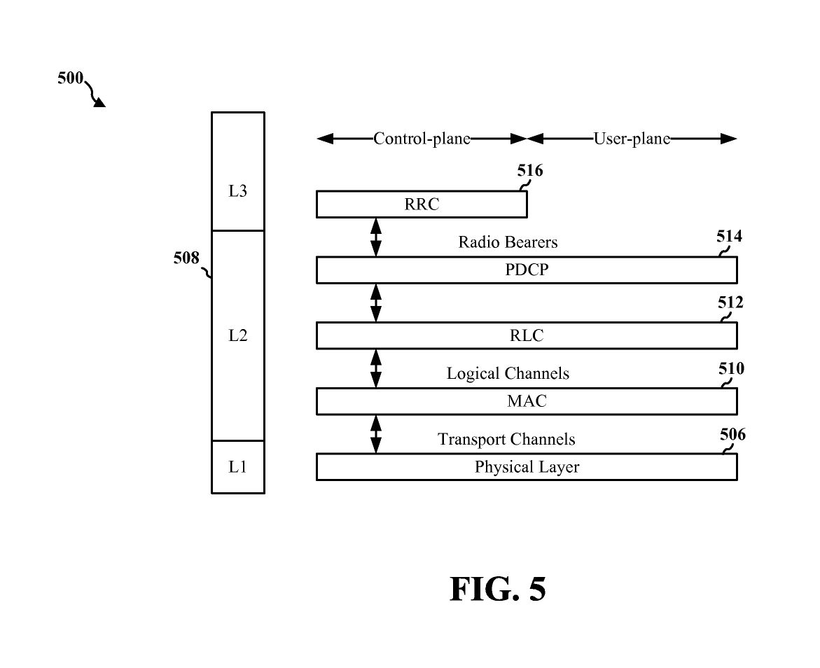

FIG. 5 is a diagram 500 illustrating an example of a radio protocol architecture for the user and control planes in LTE. The radio protocol architecture for the UE and the eNB is shown with three layers: Layer 1, Layer 2, and Layer 3. Layer 1 (L1 layer) is the lowest layer and implements various physical layer signal processing functions. The L1 layer will be referred to herein as the physical layer 506. Layer 2 (L2 layer) 508 is above the physical layer 506 and is responsible for the link between the UE and eNB over the physical layer 506.

In the user plane, the L2 layer 508 includes a media access control (MAC) sublayer 510, a radio link control (RLC) sublayer 512, and a packet data convergence protocol (PDCP) 514 sublayer, which are terminated at the eNB on the network side. Although not shown, the UE may have several upper layers above the L2 layer 508 including a network layer (e.g., IP layer) that is terminated at the PDN gateway 118 on the network side, and an application layer that is terminated at the other end of the connection (e.g., far end UE, server, etc.).

The PDCP sublayer 514 provides multiplexing between different radio bearers and logical channels. The PDCP sublayer 514 also provides header compression for upper layer data packets to reduce radio transmission overhead, security by ciphering the data packets, and handover support for UEs between eNBs. The RLC sublayer 512 provides segmentation and reassembly of upper layer data packets, retransmission of lost data packets, and reordering of data packets to compensate for out-of-order reception due to hybrid automatic repeat request (HARQ). The MAC sublayer 510 provides multiplexing between logical and transport channels. The MAC sublayer 510 is also responsible for allocating the various radio resources (e.g., resource blocks) in one cell among the UEs. The MAC sublayer 510 is also responsible for HARQ operations.

In the control plane, the radio protocol architecture for the UE and eNB is substantially the same for the physical layer 506 and the L2 layer 508 with the exception that there is no header compression function for the control plane. The control plane also includes a radio resource control (RRC) sublayer 516 in Layer 3 (L3 layer). The RRC sublayer 516 is responsible for obtaining radio resources (e.g., radio bearers) and for configuring the lower layers using RRC signaling between the eNB and the UE.

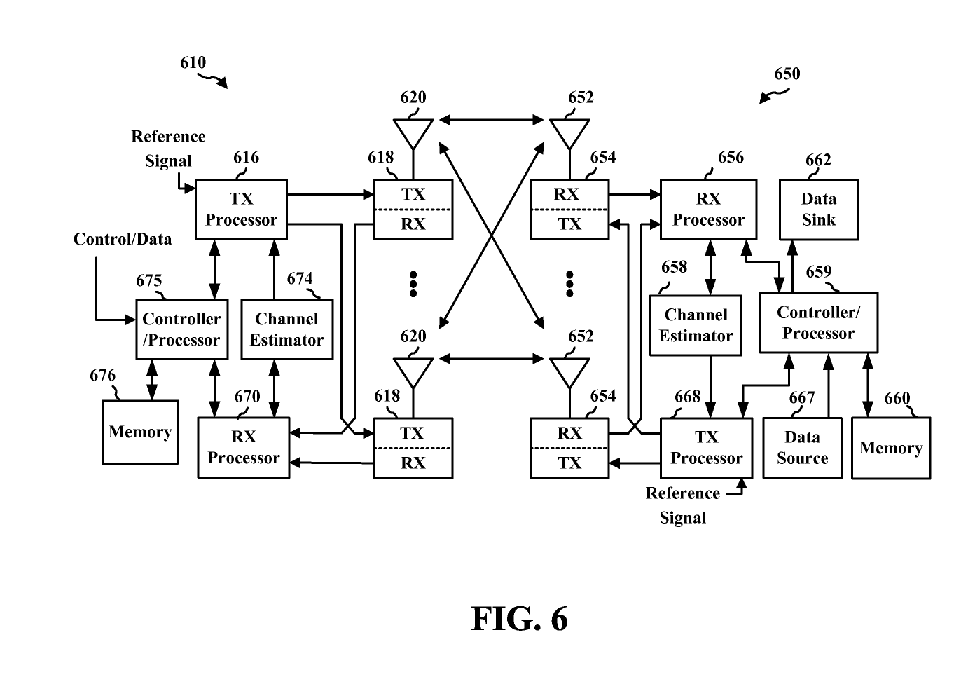

FIG. 6 is a block diagram of an eNB 610 in communication with a UE 650 in an access network. In the DL, upper layer packets from the core network are provided to a controller/processor 675. The controller/processor 675 implements the functionality of the L2 layer. In the DL, the controller/processor 675 provides header compression, ciphering, packet segmentation and reordering, multiplexing between logical and transport channels, and radio resource allocations to the UE 650 based on various priority metrics. The controller/processor 675 is also responsible for HARQ operations, retransmission of lost packets, and signaling to the UE 650.

The transmit (TX) processor 616 implements various signal processing functions for the L1 layer (i.e., physical layer). The signal processing functions include coding and interleaving to facilitate forward error correction (FEC) at the UE 650 and mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols are then split into parallel streams. Each stream is then mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 674 may be used to determine the coding and modulation scheme, as well as for spatial processing. The channel estimate may be derived from a reference signal and/or channel condition feedback transmitted by the UE 650. Each spatial stream may then be provided to a different antenna 620 via a separate transmitter 618TX. Each transmitter 618TX may modulate an RF carrier with a respective spatial stream for transmission.

At the UE 650, each receiver 654RX receives a signal through its respective antenna 652. Each receiver 654RX recovers information modulated onto an RF carrier and provides the information to the receive (RX) processor 656. The RX processor 656 implements various signal processing functions of the L1 layer. The RX processor 656 may perform spatial processing on the information to recover any spatial streams destined for the UE 650. If multiple spatial streams are destined for the UE 650, they may be combined by the RX processor 656 into a single OFDM symbol stream. The RX processor 656 then converts the OFDM symbol stream from the time-domain to the frequency domain using a Fast Fourier Transform (FFT). The frequency domain signal comprises a separate OFDM symbol stream for each subcarrier of the OFDM signal. The symbols on each subcarrier, and the reference signal, are recovered and demodulated by determining the most likely signal constellation points transmitted by the eNB 610. These soft decisions may be based on channel estimates computed by the channel estimator 658. The soft decisions are then decoded and deinterleaved to recover the data and control signals that were originally transmitted by the eNB 610 on the physical channel. The data and control signals are then provided to the controller/processor 659.

The controller/processor 659 implements the L2 layer. The controller/processor can be associated with a memory 660 that stores program codes and data. The memory 660 may be referred to as a computer-readable medium. In the UL, the controller/processor 659 provides demultiplexing between transport and logical channels, packet reassembly, deciphering, header decompression, control signal processing to recover upper layer packets from the core network. The upper layer packets are then provided to a data sink 662, which represents all the protocol layers above the L2 layer. Various control signals may also be provided to the data sink 662 for L3 processing. The controller/processor 659 is also responsible for error detection using an acknowledgement (ACK) and/or negative acknowledgement (NACK) protocol to support HARQ operations.

In the UL, a data source 667 is used to provide upper layer packets to the controller/processor 659. The data source 667 represents all protocol layers above the L2 layer. Similar to the functionality described in connection with the DL transmission by the eNB 610, the controller/processor 659 implements the L2 layer for the user plane and the control plane by providing header compression, ciphering, packet segmentation and reordering, and multiplexing between logical and transport channels based on radio resource allocations by the eNB 610. The controller/processor 659 is also responsible for HARQ operations, retransmission of lost packets, and signaling to the eNB 610.

Channel estimates derived by a channel estimator 658 from a reference signal or feedback transmitted by the eNB 610 may be used by the TX processor 668 to select the appropriate coding and modulation schemes, and to facilitate spatial processing. The spatial streams generated by the TX processor 668 may be provided to different antenna 652 via separate transmitters 654TX. Each transmitter 654TX may modulate an RF carrier with a respective spatial stream for transmission.

The UL transmission is processed at the eNB 610 in a manner similar to that described in connection with the receiver function at the UE 650. Each receiver 618RX receives a signal through its respective antenna 620. Each receiver 618RX recovers information modulated onto an RF carrier and provides the information to a RX processor 670. The RX processor 670 may implement the L1 layer.

The controller/processor 675 implements the L2 layer. The controller/processor 675 can be associated with a memory 676 that stores program codes and data. The memory 676 may be referred to as a computer-readable medium. In the UL, the control/processor 675 provides demultiplexing between transport and logical channels, packet reassembly, deciphering, header decompression, control signal processing to recover upper layer packets from the UE 650. Upper layer packets from the controller/processor 675 may be provided to the core network. The controller/processor 675 is also responsible for error detection using an ACK and/or NACK protocol to support HARQ operations.

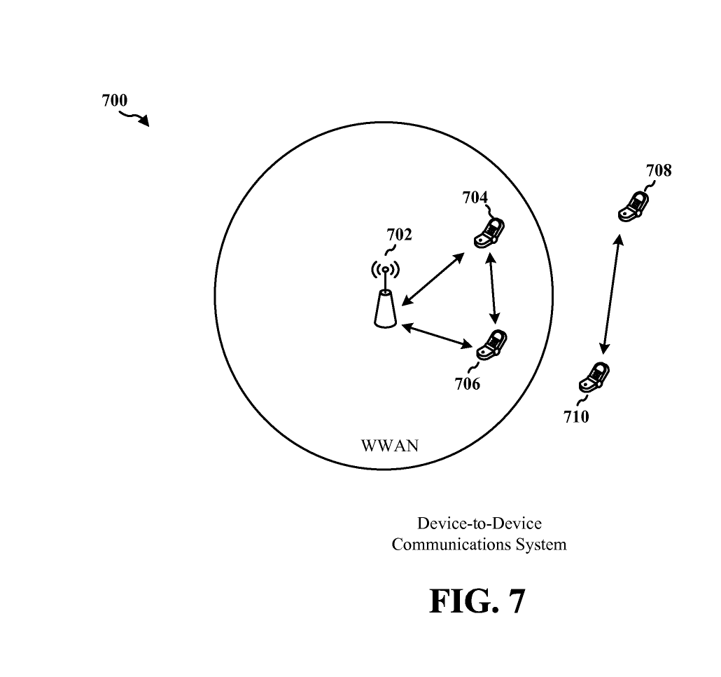

FIG. 7 is a diagram of a device-to-device communications system 700. The device-to-device communications system 700 includes a plurality of wireless devices 704, 706, 708, 710. The device-to-device communications system 700 may overlap with a cellular communications system, such as for example, a wireless wide area network (WWAN). Some of the wireless devices 704, 706, 708, 710 may communicate together in device-to-device communication using the DL/UL WWAN spectrum, some may communicate with the base station 702, and some may do both. For example, as shown in FIG. 7, the wireless devices 708, 710 are in device-to-device communication and the wireless devices 704, 706 are in device-to-device communication. The wireless devices 704, 706 are also communicating with the base station 702.

The exemplary methods and apparatuses discussed infra are applicable to any of a variety of wireless device-to-device communications systems, such as for example, a wireless device-to-device communication system based on FlashLinQ, WiMedia, Bluetooth, ZigBee, or Wi-Fi based on the IEEE 802.11 standard. To simplify the discussion, the exemplary methods and apparatus are discussed within the context of LTE. However, one of ordinary skill in the art would understand that the exemplary methods and apparatuses are applicable more generally to a variety of other wireless device-to-device communication systems.

A wireless network supporting device-to-device (D2D) communications systems (or peer-to-peer communications systems) may have many devices. The ability for these devices to perform peer-to-peer (P2P) communications is increasingly important in mobile applications including social networking applications. Devices may engage in P2P communications by discovering other devices within proximity. A device may broadcast a peer discovery signal that conveys a peer discovery expression identifying the device. The device may also detect a peer discovery signal from other devices.

Ideally, devices should be able to communicate with as many devices as possible by discovering as many devices as possible within proximity. Due to physical objects like buildings, walls, and other hindrances to RF transmissions, however, geographical vicinity does not necessarily imply wireless vicinity. In urban areas especially, the presence of physical objects may significantly reduce the signal-to-noise ratio (SNR) of a received RF transmission from a neighboring device. This may result in devices that are interested in communicating with each other and also are in close proximity with each other but are not able to discover each other. As such, a need exists to facilitate peer discovery at low SNR.

Referring again to FIG. 7, the UE 708 may perform peer discovery by periodically transmitting a coded peer discovery message to the UE 710. To code a peer discovery message, the UE 708 may use a peer discovery expression and add cyclic redundancy check (CRC) bits to the peer discovery expression. The peer discovery expression is a bit stream containing information that identifies the UE 708. The UE 708 may transmit the coded peer discovery message to the UE 710 by selecting a resource block in a peer discovery period (e.g., LTE-D discovery period) and periodically transmitting the same peer discovery expression on the same resource block. In another configuration, the peer discovery expression may hop resource blocks in a predetermined pattern. The UE 710, which is interested in discovering other UEs, listens to all resource blocks and tries to decode the peer discovery expressions in each resource block. Whenever the coded peer discovery expression passes the CRC check, that implies that the reception and decoding were error free, and the UE 710 can be confident of discovering a device for peer communications. More peer discoveries, however, can be made by enabling good decoding of coded peer discovery messages at low SNR.

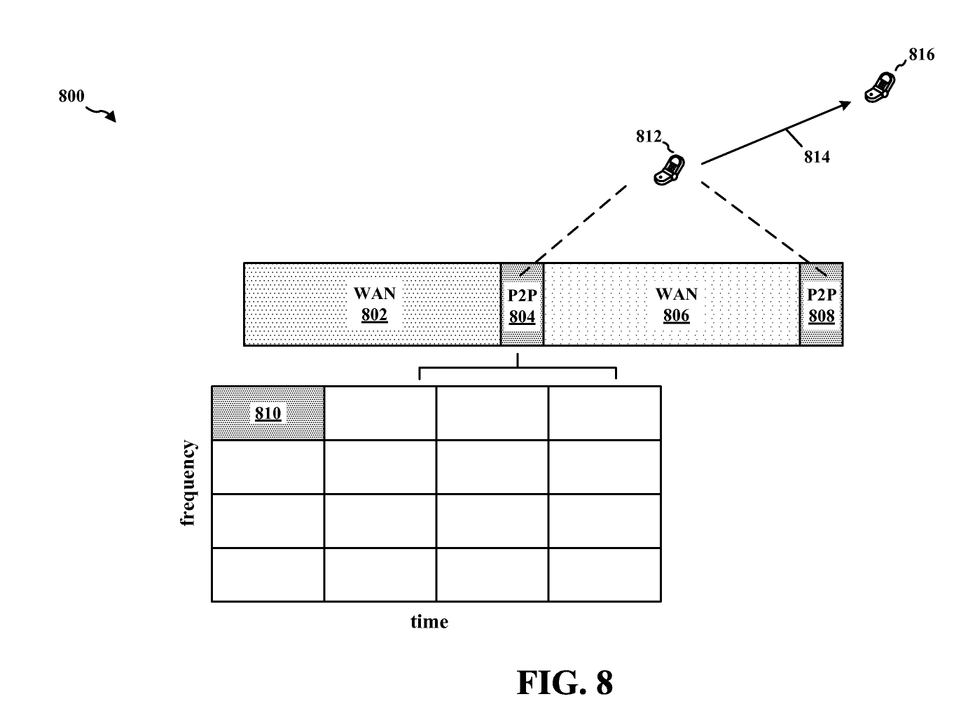

FIG. 8 is a diagram 800 illustrating an exemplary method for improving link budget in peer discovery using multiple redundant versions. One example protocol that uses multiple redundant versions is HARQ, which is a MAC protocol that relies on generations of multiple redundant versions (or code-words of different redundancy levels) for data. By using multiple redundant versions of a coded peer discovery message, the received redundancy versions may be combined over different times to increase transmission efficiency. To illustrate, a first redundancy version is transmitted. If the reception is unsuccessful then a second redundancy version is sent and so on until the information bits are successfully decoded based on the combined redundancy versions. This method is more power and spectrum efficient than simple repetitive transmission of the same code-word. FIG. 8 illustrates an example of peer discovery using multiple redundant versions. In FIG. 8, wireless resources may be partitioned into two types. One type may include WAN resources 802, 806 (e.g., LTE WAN resources) for transmitting data. Another type may include P2P resources 804, 808 (e.g., LTE P2P/D2D resources) for peer discovery. P2P resources may be periodically allocated, and each set of P2P resources may contain several resource blocks such as the resource block pair 810 in one subframe. Unlike data transmissions on WAN resources 802, 806, where new data is expected to be sent during every transmission, peer discovery expressions over P2P resources 804, 808 may be the same (or similar) for each device. The coded peer discovery messages, received over consecutive discovery periods on resource blocks allotted to a particular UE (e.g., a UE 812) for transmission of peer discovery messages, are not independent. Rather, the coded peer discovery messages are transmissions of the same expression, and therefore, are highly correlated. For example, referring to FIG. 8, if P2P resources 804 and 808 have been assigned to a UE 812 for transmitting coded peer discovery messages 814 to a UE 816, those coded peer discovery messages 814 may be correlated. As a result, the UE 816 may be able to decode the coded peer discovery messages 814 received at low SNR by combining the coded peer discovery messages 814 received over different times.

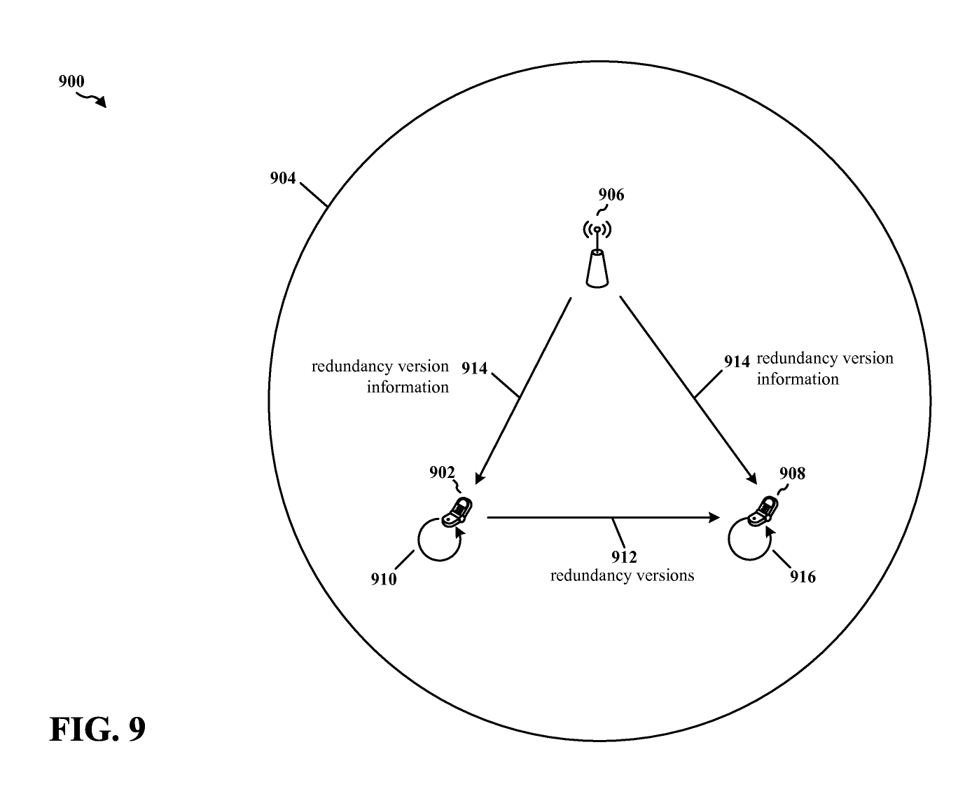

FIG. 9 is a diagram 900 for illustrating an exemplary method for improving link budget in peer discovery. In FIG. 9, a UE 902 may be within a cell 904 of a base station 906. A UE 908 may also be within the cell 904 of the base station 906. The UE 902 may be interested in P2P communications and may perform a series of steps 910 for peer discovery. The UE 902 may code a peer discovery message for peer discovery. In one configuration, coding the peer discovery message includes appending CRC bits to a peer discovery expression and encoding the peer discovery expression and the CRC bits. For example, in an LTE network, the UE 902 may append CRC bits to a peer discovery expression and encode the peer discovery expression and the CRC bits.

The UE 902 may generate a number (or plurality) of different redundancy versions 912 of the coded peer discovery message. In one configuration, generating the different redundancy versions 912 includes puncturing a different set of bits for each of the different redundancy versions 912 of the coded peer discovery message. For example, the UE 902 may generate five different redundancy versions 912 of the coded peer discovery message by puncturing a different set of bits for each of the five different redundancy versions 912 of the coded peer discovery message.

The UE 902 may transmit each of the different redundancy versions 912 of the coded peer discovery message in a different allocated time period to the UE 908. For example, UE 902 may transmit one redundancy version 912 in P2P resource 804 and a different redundancy version 912 in P2P resource 808.

In one configuration, the UE 902 may receive instructions for sending each of the different redundancy versions from the base station 906. The UE 902 may be synchronized to the base station 906 given that the UE 902 is the cell 904. The base station 906 may determine an appropriate order for transmitting each of the different redundancy versions 912. The base station 906 may transmit the redundancy version information 914 to UEs 902, 908. The redundancy version information 914 may include an indication of a transmission order of the different redundancy versions 912. The UE 902 may keep transmitting each of the different redundancy versions 912 based on the transmission order indicated in the redundancy version information 914. Each of the different redundancy versions 912 may be separately decodable. Thus, in a particular discovery period, the redundancy versions used by different devices are known to each other. For example, the UE 902 may have five different redundancy versions 912 for transmission to the UE 908. The UE 902 may receive redundancy version information 914 from the base station 906 and transmit each of the five different redundancy versions 912 based on the received redundancy version information 914.

In one configuration, the UE 902 may transmit each of the different redundancy versions 912 without receiving a negative acknowledgement indicating a request for the different redundancy versions. For example, the UE 902 may transmit each of the different redundancy versions 912 without receiving a negative acknowledgment from the UE 908 indicating that a redundancy version 912 was not successfully received.

After the UE 902 transmits at least one redundancy versions 912 to UE 908, the UE 908 may receive the at least one redundancy version 912 of the coded peer discovery message. The UE 908 may store the at least one received redundancy version 912 in a buffer or memory. The UE 908 may receive redundancy version information 914 from the base station 906. The redundancy version information 914 may include information indicating the transmission order of the redundancy versions 912. The UE 908 may attempt to decode 916 the received at least one redundancy version 912 of the coded peer discovery message based on the redundancy version information 914. The UE 908 may determine whether the decoding attempt was successful based on the CRC. If the decoding was not successful, the UE 908 may receive a subsequent redundancy version 912 of the coded peer discovery message. In one configuration, the subsequent redundancy version 912 may be received without the UE 908 sending a negative acknowledgement requesting the subsequent redundancy version 912. After receiving the subsequent redundancy version 912 of the coded peer discovery message, the UE 908 may combine the subsequent redundancy version 912 of the coded peer discovery message with the at least one redundancy version 912 of the coded peer discovery message. In one configuration, combining the subsequent redundancy version 912 of the coded peer discovery message with the at least one redundancy version 912 of the coded peer discovery message is based on a log likelihood ratio. After combining the redundancy versions 912, the UE 908 may successfully decode the combined subsequent redundancy version 912 and the at least one redundancy version 912 of the coded peer discovery message. In one configuration, the UE 908 may successfully decode the combination based on the redundancy version information 914 received from the base station 906. If the decoding is not successful, the UE 908 may continue to receive and combine additional redundancy versions 912 of the coded peer discovery message.

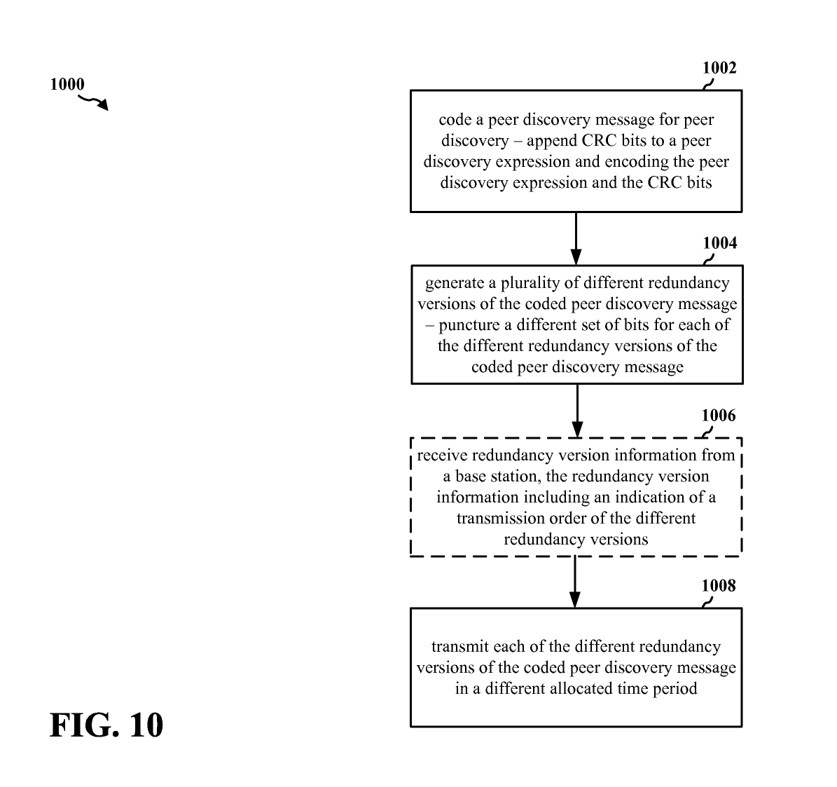

FIG. 10 is a flow chart 1000 of a method for improving link budget in peer discovery. The method may be performed by a UE (e.g., the UE 902). At step 1002, the UE may code a peer discovery message for peer discovery. In one configuration, the peer discovery message may be coded by appending CRC bits to a peer discovery expression and encoding the peer discovery expression and the CRC bits. For example, in an LTE network, the UE 902 may append CRC bits to a peer discovery expression and encode the peer discovery expression and the CRC bits.

At step 1004, the UE may generate a plurality of different redundancy versions of the coded peer discovery message. In one configuration, the UE may generate a plurality of different redundancy versions by puncturing a different set of bits for each of the different redundancy versions of the coded peer discovery message. For example, the UE 902 may generate four different redundancy versions 912 of the coded peer discovery message by puncturing a different set of bits for each of the four different redundancy versions 912 of the coded peer discovery message.

At step 1006, the UE may receive redundancy version information from a base station. The redundancy version information may include an indication of a transmission order of the different redundancy versions. For example, the UE 902 may have four different redundancy versions 912 for transmission to the UE 908. The UE 902 may receive redundancy version information 914 from the base station 906 and the redundancy version information 914 may indicate a transmission order for each of the four different redundancy versions 912.

At step 1008, the UE may transmit each of the different redundancy versions of the coded peer discovery message in a different allocated time period. The UE may transmit each of the different redundancy versions of the coded peer discovery message based on the received redundancy version information received from the base station. For example, UE 902 may have four different redundancy versions 912 for transmission to the UE 908. The UE 902 may receive redundancy version information 914 from the base station 906 and transmit each of the four different redundancy versions 912 based on received redundancy version information 914.

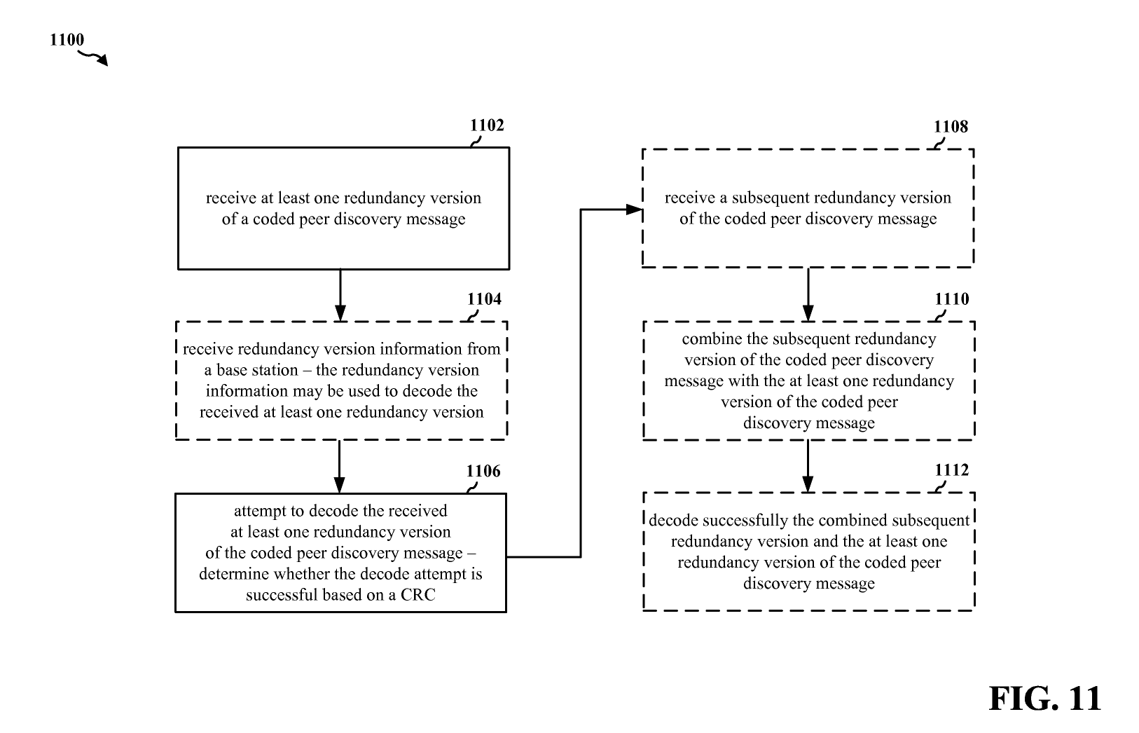

FIG. 11 is a flow chart 1100 of a method for improving link budget in peer discovery. The method may be performed by a UE (e.g., the UE 908). At step 1102, the UE may receive at least one redundancy version of a coded peer discovery message. The UE may store the at least one received redundancy version in a buffer or memory. For example, the UE 908 may receive a redundancy version 912 from the UE 902. The UE 908 may store the received redundancy version 912 in a buffer.

At step 1104, the UE may receive redundancy version information from a base station. The redundancy version information may include information indicating the transmission order of the redundancy versions and this information may be used to decode the received at least one redundancy version. For example, the UE 908 may receive redundancy version information 914 from the base station 906. The redundancy version information 914 may indicate that the received redundancy version 912 is the second of four redundancy versions 912.

At step 1106, the UE may attempt to decode the received at least one redundancy version of the coded peer discovery message. The UE may determine whether the decode attempt is successful based on a CRC. For example, the UE 908 may attempt to decode the received at least one redundancy version 912 of the coded peer discovery message based on the redundancy version information 914. The UE 908 may determine whether the decoding attempt was successful based on the CRC.

At step 1108, the UE may receive a subsequent redundancy version of the coded peer discovery message. In one configuration, the subsequent redundancy version may be received without the UE sending a negative acknowledgement requesting the subsequent redundancy version. For example, if the decode attempt was unsuccessful, the UE 908 may receive a subsequent redundancy version 912 of the coded peer discovery message without having to transmit a negative acknowledgement to the UE 902.

At step 1110, the UE may combine the subsequent redundancy version of the coded peer discovery message with the at least one redundancy version of the coded peer discovery message. In one configuration, the UE may combine the subsequent redundancy version of the coded peer discovery message with the at least one redundancy version of the coded peer discovery message based on a log likelihood ratio. For example, if the previous decoding attempt was unsuccessful, the UE 908 may combine the subsequent redundancy version 912 of the coded peer discovery message with the at least one redundancy version 912 of the coded peer discovery message based on a log likelihood ratio to obtain a better redundancy version in low SNR.

At step 1112, the UE may decode successfully the combined subsequent redundancy version and the at least one redundancy version of the coded peer discovery message. For example, the UE 908 may successfully decode the combination based on the redundancy version information 914 received from the base station 906. If the decoding is not successful, the UE 908 may continue to receive, combine, and attempt to decode additional redundancy versions 912 of the coded peer discovery message.

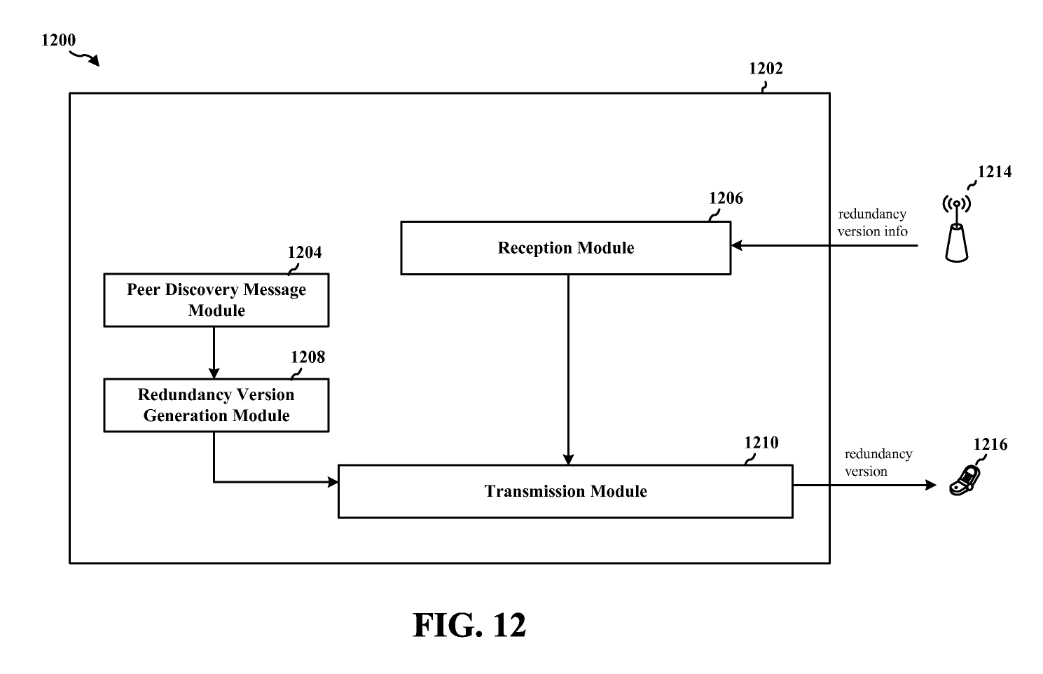

FIG. 12 is a conceptual data flow diagram 1200 illustrating the data flow between different modules/means/components in an exemplary apparatus 1202. The apparatus may be a UE (e.g., the UE 902). The apparatus may include a peer discovery message module 1204, a reception module 1206, a redundancy version generation module 1208, and a transmission module 1210.

The peer discovery message module 1204 may be configured to code a peer discovery message for peer discovery. In one configuration, the peer discovery message module 1204 may be configured to code a peer discovery message for peer discovery by appending CRC bits to a peer discovery expression and encoding the peer discovery expression and the CRC bits.

The redundancy version generation module 1208 may be configured to generate a plurality of different redundancy versions of the coded peer discovery message. The transmission module 1210 may be configured to transmit each of the different redundancy versions of the coded peer discovery message in a different allocated time period to a UE 1216. The redundancy version generation module 1208 may be configured generate the plurality of different redundancy versions by puncturing a different set of bits for each of the different redundancy versions of the coded peer discovery message. The reception module 1206 may be configured to receive redundancy version information from a base station 1214. The redundancy version information may include an indication of a transmission order of the different redundancy versions. Each of the different redundancy versions may be transmitted by the transmission module 1210 based on the transmission order indicated in the redundancy version information. Each of the different redundancy versions may be transmitted without receiving a negative acknowledgment indicating a request for the different redundancy versions.

The apparatus may include additional modules that perform each of the steps of the algorithm in the aforementioned flow charts of FIG. 10. As such, each step in the aforementioned flow charts of FIG. 10 may be performed by a module and the apparatus may include one or more of those modules. The modules may be one or more hardware components specifically configured to carry out the stated processes/algorithm, implemented by a processor configured to perform the stated processes/algorithm, stored within a computer-readable medium for implementation by a processor, or some combination thereof.

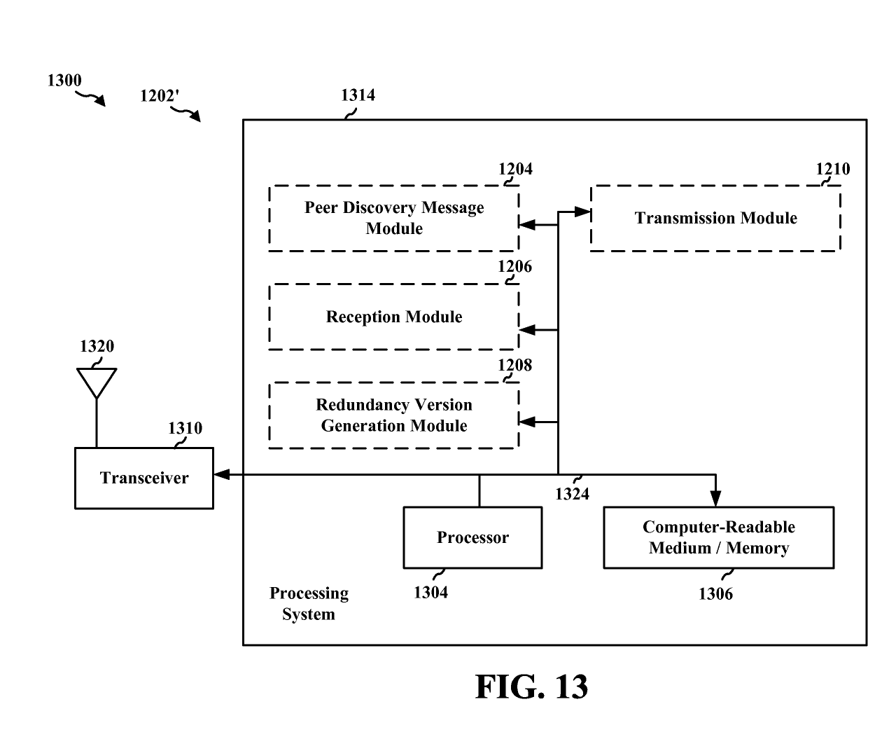

FIG. 13 is a diagram 1300 illustrating an example of a hardware implementation for an apparatus 1202′ employing a processing system 1314. The processing system 1314 may be implemented with a bus architecture, represented generally by the bus 1324. The bus 1324 may include any number of interconnecting buses and bridges depending on the specific application of the processing system 1314 and the overall design constraints. The bus 1324 links together various circuits including one or more processors and/or hardware modules, represented by the processor 1304, the modules 1204, 1206, 1208, 1210, and the computer-readable medium/memory 1306. The bus 1324 may also link various other circuits such as timing sources, peripherals, voltage regulators, and power management circuits, which are well known in the art, and therefore, will not be described any further.

The processing system 1314 may be coupled to a transceiver 1310. The transceiver 1310 is coupled to one or more antennas 1320. The transceiver 1310 provides a means for communicating with various other apparatus over a transmission medium. The transceiver 1310 receives a signal from the one or more antennas 1320, extracts information from the received signal, and provides the extracted information to the processing system 1314, specifically the reception module 1206. In addition, the transceiver 1310 receives information from the processing system 1314, specifically the transmission module 1210, and based on the received information, generates a signal to be applied to the one or more antennas 1320. The processing system 1314 includes a processor 1304 coupled to a computer-readable medium/memory 1306. The processor 1304 is responsible for general processing, including the execution of software stored on the computer-readable medium/memory 1306. The software, when executed by the processor 1304, causes the processing system 1314 to perform the various functions described supra for any particular apparatus. The computer-readable medium/memory 1306 may also be used for storing data that is manipulated by the processor 1304 when executing software. The processing system further includes at least one of the modules 1204, 1206, 1208, 1210. The modules may be software modules running in the processor 1304, resident/stored in the computer readable medium/memory 1306, one or more hardware modules coupled to the processor 1304, or some combination thereof. The processing system 1314 may be a component of the UE 650 and may include the memory 660 and/or at least one of the TX processor 668, the RX processor 656, and the controller/processor 659.

In one configuration, the apparatus 1202/1202′ for wireless communication includes means for coding a peer discovery message for peer discovery. The apparatus includes means for generating a plurality of different redundancy versions of the coded peer discovery message. The apparatus includes means for transmitting each of the different redundancy versions of the coded peer discovery message in a different allocated time period. The means for coding the peer discovery message may be configured to append CRC bits to a peer discovery expression and encode the peer discovery expression and the CRC bits. The means for generating the plurality of different redundancy versions may be configured to puncture a different set of bits for each of the different redundancy versions of the coded peer discovery message. The apparatus may also include means for receiving redundancy version information from a base station. The redundancy version information may include an indication of a transmission order of the different redundancy versions. Each of the different redundancy versions may be transmitted based on the transmission order indicated in the redundancy version information. Also, each of the different redundancy versions may be transmitted without receiving a negative acknowledgment indicating a request for the different redundancy versions.

The aforementioned means may be one or more of the aforementioned modules of the apparatus 1202 and/or the processing system 1314 of the apparatus 1202′ configured to perform the functions recited by the aforementioned means. As described supra, the processing system 1314 may include the TX Processor 668, the RX Processor 656, and the controller/processor 659. As such, in one configuration, the aforementioned means may be the TX Processor 668, the RX Processor 656, and the controller/processor 659 configured to perform the functions recited by the aforementioned means.

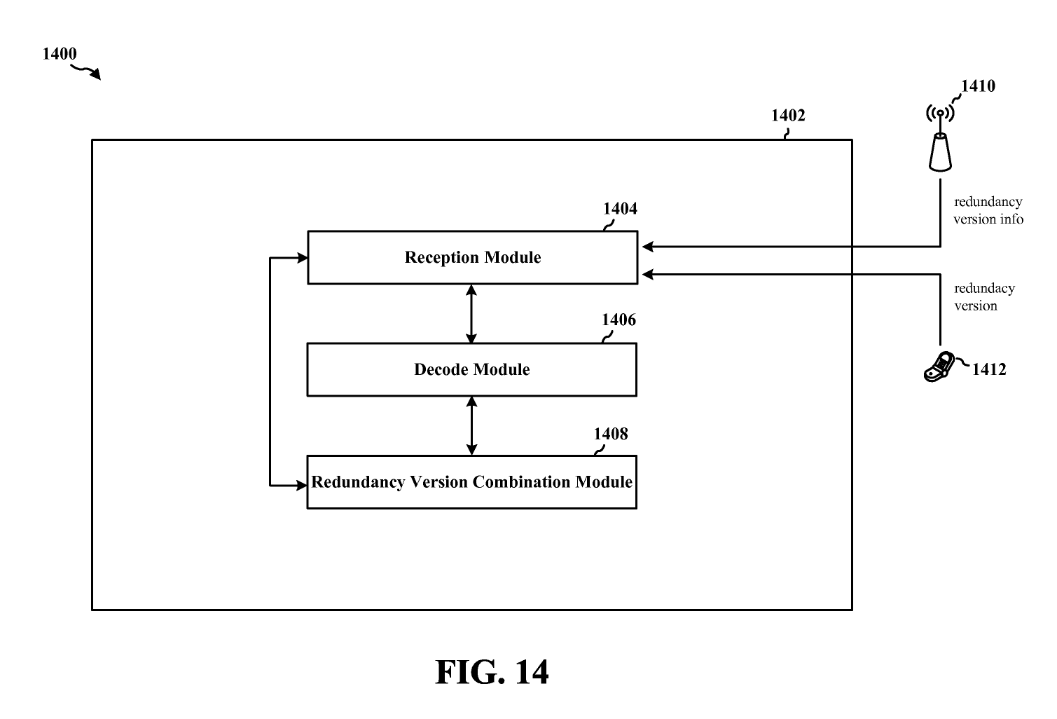

FIG. 14 is a conceptual data flow diagram 1400 illustrating the data flow between different modules/means/components in an exemplary apparatus 1402. The apparatus may be a UE (e.g., the UE 908). The apparatus may include a reception module 1404, a decode module 1406, and a redundancy version combination module 1408. The reception module 1404 may be configured to receive at least one redundancy version of a coded peer discovery message from a UE 1412. The decode module 1406 may be configured to attempt to decode the received at least one redundancy version of the coded peer discovery message. The decode module 1406 may be configured to attempt to decode by determining whether the at least one redundancy version of the coded peer discovery message has been decoded successfully based on a cyclic redundancy check.

In one configuration, if the received at least one redundancy version of the coded peer discovery message is decoded unsuccessfully, the reception module 1404 may be configured to receive a subsequent redundancy version of the coded peer discovery message. The redundancy version combination module 1408 may be configured to combine the subsequent redundancy version of the coded peer discovery message with the at least one redundancy version of the coded peer discovery message. The decode module 1406 may be configured to decode successfully the combined subsequent redundancy version and the at least one redundancy version of the coded peer discovery message. The redundancy version combination module 1408 may be configured to combine the subsequent redundancy version of the coded peer discovery message with the at least one redundancy version of the coded peer discovery message based on a log likelihood ratio. The subsequent redundancy version may be received without sending a negative acknowledgment requesting the subsequent redundancy version. The reception module 1404 may be configured to receive redundancy version information from a base station 1410. The redundancy version information may include information on the transmission order of the at least one redundancy version of the coded peer discovery message. The decode module 1406 may be configured to decode the received at least one redundancy version of the coded peer discovery message based on the redundancy version information received from the base station 1410.

The apparatus may include additional modules that perform each of the steps of the algorithm in the aforementioned flow charts of FIG. 11. As such, each step in the aforementioned flow charts of FIG. 11 may be performed by a module and the apparatus may include one or more of those modules. The modules may be one or more hardware components specifically configured to carry out the stated processes/algorithm, implemented by a processor configured to perform the stated processes/algorithm, stored within a computer-readable medium for implementation by a processor, or some combination thereof.

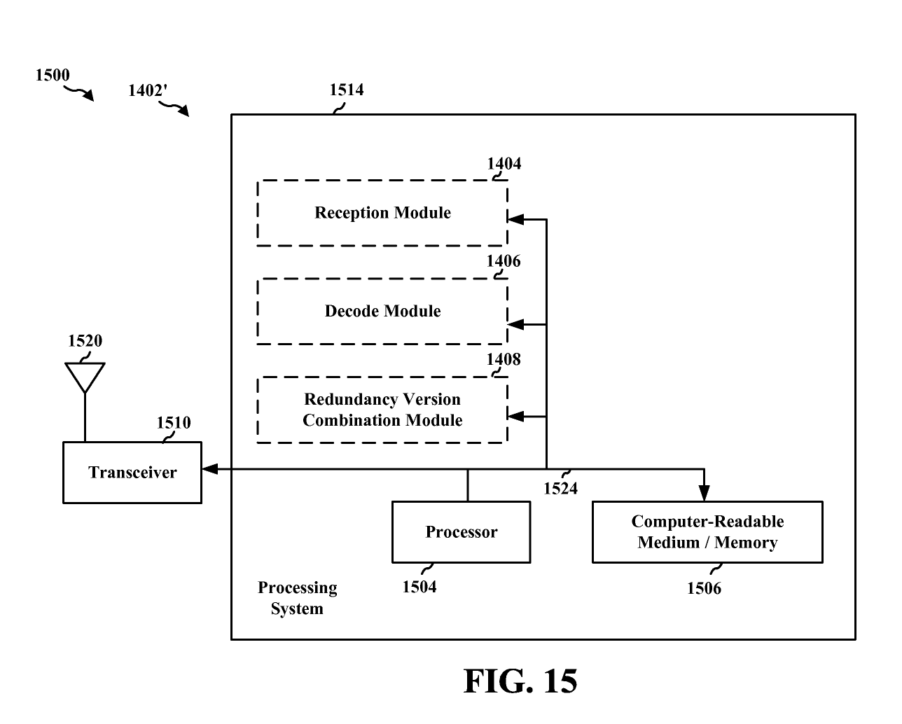

FIG. 15 is a diagram 1500 illustrating an example of a hardware implementation for an apparatus 1402′ employing a processing system 1514. The processing system 1514 may be implemented with a bus architecture, represented generally by the bus 1524. The bus 1524 may include any number of interconnecting buses and bridges depending on the specific application of the processing system 1514 and the overall design constraints. The bus 1524 links together various circuits including one or more processors and/or hardware modules, represented by the processor 1504, the modules 1404, 1406, 1408, and the computer-readable medium/memory 1506. The bus 1524 may also link various other circuits such as timing sources, peripherals, voltage regulators, and power management circuits, which are well known in the art, and therefore, will not be described any further.

The processing system 1514 may be coupled to a transceiver 1510. The transceiver 1510 is coupled to one or more antennas 1520. The transceiver 1510 provides a means for communicating with various other apparatus over a transmission medium. The transceiver 1510 receives a signal from the one or more antennas 1520, extracts information from the received signal, and provides the extracted information to the processing system 1514, specifically the reception module 104. In addition, the transceiver 1510 receives information from the processing system 1514, and based on the received information, generates a signal to be applied to the one or more antennas 1520. The processing system 1514 includes a processor 1504 coupled to a computer-readable medium/memory 1506. The processor 1504 is responsible for general processing, including the execution of software stored on the computer-readable medium/memory 1506. The software, when executed by the processor 1504, causes the processing system 1514 to perform the various functions described supra for any particular apparatus. The computer-readable medium/memory 1506 may also be used for storing data that is manipulated by the processor 1504 when executing software. The processing system further includes at least one of the modules 1404, 1406, 1408. The modules may be software modules running in the processor 1504, resident/stored in the computer readable medium/memory 1506, one or more hardware modules coupled to the processor 1504, or some combination thereof. The processing system 1514 may be a component of the UE 650 and may include the memory 660 and/or at least one of the TX processor 668, the RX processor 656, and the controller/processor 659.

In one configuration, the apparatus 1402/1402′ for wireless communication includes means for receiving at least one redundancy version of a coded peer discovery message. The apparatus may include means for attempting to decode the received at least one redundancy version of the coded peer discovery message. The means for attempting to decode may be configured to determine whether the at least one redundancy version of the coded peer discovery message has been decoded successfully based on a cyclic redundancy check.

In one configuration, the apparatus may include means for receiving a subsequent redundancy version of the coded peer discovery message (the apparatus receives the subsequent redundancy version when the received at least one redundancy version of the coded peer discovery message is decoded unsuccessfully), means for combining the subsequent redundancy version of the coded peer discovery message with the at least one redundancy version of the coded peer discovery message, and means for decoding successfully the combined subsequent redundancy version and the at least one redundancy version of the coded peer discovery message. The means for combining the subsequent redundancy version of the coded peer discovery message may be based on a log likelihood ratio. The subsequent redundancy version may be received without sending a negative acknowledgment requesting the subsequent redundancy version. The apparatus may include means for receiving redundancy version information from a base station. The apparatus may attempt to decode the received at least one redundancy version of the coded peer discovery message based on the redundancy version information received from the base station. The redundancy version information may include information on the transmission order of the at least one redundancy version of the coded peer discovery message.

The aforementioned means may be one or more of the aforementioned modules of the apparatus 1402 and/or the processing system 1514 of the apparatus 1402′ configured to perform the functions recited by the aforementioned means. As described supra, the processing system 1514 may include the TX Processor 668, the RX Processor 656, and the controller/processor 659. As such, in one configuration, the aforementioned means may be the TX Processor 668, the RX Processor 656, and the controller/processor 659 configured to perform the functions recited by the aforementioned means.

It is understood that the specific order or hierarchy of steps in the processes/flow charts disclosed is an illustration of exemplary approaches. Based upon design preferences, it is understood that the specific order or hierarchy of steps in the processes/flow charts may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A method of wireless communication of a user equipment (UE), comprising:
coding a peer discovery message for peer discovery;
generating a plurality of different redundancy versions of the coded peer discovery message; and
transmitting each of the different redundancy versions of the coded peer discovery message in a different allocated time period.

2. The method of claim 1, wherein the coding the peer discovery message comprises appending cyclic redundancy check (CRC) bits to a peer discovery expression and encoding the peer discovery expression and the CRC bits.

3. The method of claim 1, wherein the generating the plurality of different redundancy versions comprises puncturing a different set of bits for each of the different redundancy versions of the coded peer discovery message.

4. The method of claim 1, further comprising receiving redundancy version information from a base station, the redundancy version information including an indication of a transmission order of the different redundancy versions, wherein each of the different redundancy versions is transmitted based on the transmission order indicated in the redundancy version information.

5. The method of claim 1, wherein each of the different redundancy versions is transmitted without receiving a negative acknowledgment indicating a request for the different redundancy versions.

6. A method of wireless communication of a user equipment (UE), comprising:
receiving at least one redundancy version of a coded peer discovery message; and
attempting to decode the received at least one redundancy version of the coded peer discovery message.

7. The method of claim 6, wherein the attempting to decode further comprises determining whether the at least one redundancy version of the coded peer discovery message has been decoded successfully based on a cyclic redundancy check.

8. The method of claim 6, wherein the received at least one redundancy version of the coded peer discovery message is decoded unsuccessfully, and the method further comprises:
receiving a subsequent redundancy version of the coded peer discovery message;
combining the subsequent redundancy version of the coded peer discovery message with the at least one redundancy version of the coded peer discovery message; and
decoding successfully the combined subsequent redundancy version and the at least one redundancy version of the coded peer discovery message.

9. The method of claim 8, wherein the combining the subsequent redundancy version of the coded peer discovery message is based on a log likelihood ratio.

10. The method of claim 8, wherein the subsequent redundancy version is received without sending a negative acknowledgment requesting the subsequent redundancy version.

11. The method of claim 6, further comprising receiving redundancy version information from a base station, wherein the UE attempts to decode the received at least one redundancy version of the coded peer discovery message based on the redundancy version information received from the base station.

12. The method of claim 11, wherein the redundancy version information includes information on the transmission order of the at least one redundancy version of the coded peer discovery message.

13. An apparatus for wireless communication, comprising:
means for coding a peer discovery message for peer discovery;
means for generating a plurality of different redundancy versions of the coded peer discovery message; and
means for transmitting each of the different redundancy versions of the coded peer discovery message in a different allocated time period.

14. The apparatus of claim 13, wherein the means for coding the peer discovery message is configured to append cyclic redundancy check (CRC) bits to a peer discovery expression and encode the peer discovery expression and the CRC bits.

15. The apparatus of claim 13, wherein the means for generating the plurality of different redundancy versions is configured to puncture a different set of bits for each of the different redundancy versions of the coded peer discovery message.

16. The apparatus of claim 13, further comprising means for receiving redundancy version information from a base station, the redundancy version information including an indication of a transmission order of the different redundancy versions, wherein each of the different redundancy versions is transmitted based on the transmission order indicated in the redundancy version information.

17. The apparatus of claim 13, wherein each of the different redundancy versions is transmitted without receiving a negative acknowledgment indicating a request for the different redundancy versions.
